(19) United States
(12) Patent Application Publication
(10) Pub. No.: US 2025/0336901 A1
(43) Pub. Date: Oct. 30, 2025

(54) PACKAGES INCLUDING INTERCONNECT DIE EMBEDDED IN PACKAGE SUBSTRATES

(71) Applicant: Taiwan Semiconductor Manufacturing Co., Ltd., Hsinchu (TW)

(72) Inventors: Sheng-Chi Lin, Hsinchu (TW); Hao-Cheng Hou, Hsinchu (TW); Tsung-Ding Wang, Tainan (TW); Chien-Hsun Lee, Chu-tung Town (TW); Shang-Yun Hou, Jubei City (TW)

(21) Appl. No.: 19/264,761

(22) Filed: Jul. 9, 2025

Related U.S. Application Data
(62) Division of application No. 17/806,329, filed on Jun. 10, 2022.
(60) Provisional application No. 63/322,862, filed on Mar. 23, 2022.

(51) Int. Cl. H01L 25/10; H01L 21/48; H01L 23/00; H01L 23/31; H01L 23/498; H01L 23/538; H01L 25/00; H01L 25/18

(52) U.S. Cl. CPC H01L 25/105; H01L 21/4857; H01L 23/3121; H01L 23/49822; H01L 23/5381; H01L 23/5385; H01L 24/24; H01L 25/18; H01L 25/50; H01L 24/13; H01L 24/16; H01L 24/32; H01L 24/73; H01L 2224/13025; H01L 2224/16227; H01L 2224/24227; H01L 2224/244; H01L 2224/25174; H01L 2224/32225; H01L 2224/73204; H01L 2225/1035; H01L 2225/1058

(57) ABSTRACT

A method includes forming a build-up package substrate, which includes forming a first plurality of redistribution lines (RDLs) and a second plurality of RDLs, forming a first plurality of through-vias on the first plurality of RDLs, bonding an interconnect die to the second plurality of RDLs, encapsulating the interconnect die and the first plurality of through-vias in a first encapsulant, and forming a third plurality of RDLs over the first encapsulant. The third plurality of RDLs are electrically connected to the first plurality of through-vias. An organic package substrate is bonded to the build-up package substrate. The build-up package substrate and the organic package substrate in combination form a compound organic package substrate. A first package component and a second package component are bonded to the compound organic package substrate, and are electrically interconnected through the interconnect die.

### PRIORITY CLAIM AND CROSS-REFERENCE

This application is a divisional of U.S. patent application Ser. No. 17/806,329, filed Jun. 10, 2022, and entitled “Packages Including Interconnect Die Embedded in Package Substrates,” which claims the benefit of the following provisionally filed U.S. Patent application: Application No. 63/322,862, filed on Mar. 23, 2022, and entitled “Novel Design for Die Integration with Substrate;” which application is hereby incorporated herein by reference.

### BACKGROUND

Interconnect dies have been used for electrically interconnecting device dies and packages, etc. Currently, the interconnect dies were embedded in Chip-on-Wafer-on-Substrate (CoWoS) packages. The CoWoS packages are bonded on package substrates. This design has its limitations. For example, the area occupied by the interconnect dies limits electrical routing and input/output ability. The insertion loss is also high. Since the interconnect dies are embedded, the resulting CoWoS packages are large, and the reliability in the joints between the CoWoS packages and the package substrates is adversely affected. Warpage may also be high due to the large CoWoS packages.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-16 illustrate the cross-sectional views of intermediate stages in the formation of a package in accordance with some embodiments.

FIGS. 17-19 and 20-22 illustrate the cross-sectional views of intermediate stages in the formation of some package components used in the package in accordance with some embodiments.

FIGS. 23-26 illustrate the cross-sectional views of some package components used in the package in accordance with some embodiments.

FIG. 27 illustrates a magnified view of a portion of the package in accordance with some embodiments.

FIG. 28 illustrates the cross-sectional view of an interconnect die in accordance with some embodiments.

FIG. 29 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A packaging process and the resulting packages are provided. In accordance with some embodiments, a build-up package substrate is built layer-by-layer, and an interconnect die is embedded therein. The build-up package substrate may be bonded with another package component such as an organic substrate to form a compound substrate. Discrete package components such as device dies, High-Bandwidth Memories (HBMs), Chip-on-Wafer (CoW) packages, and the like may be bonded directly to the compound substrate. Since the interconnect die is built in the compound substrate, rather than being embedded in the Chip-on-Wafer-on-Substrate (CoWoS) packages that are bonded on package substrate, the warpage is reduced, and the yield is improved. The insertion loss is also reduced. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

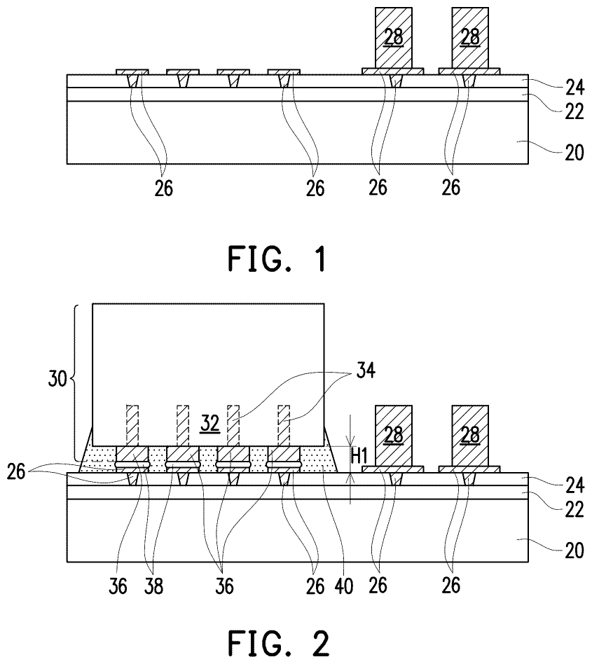

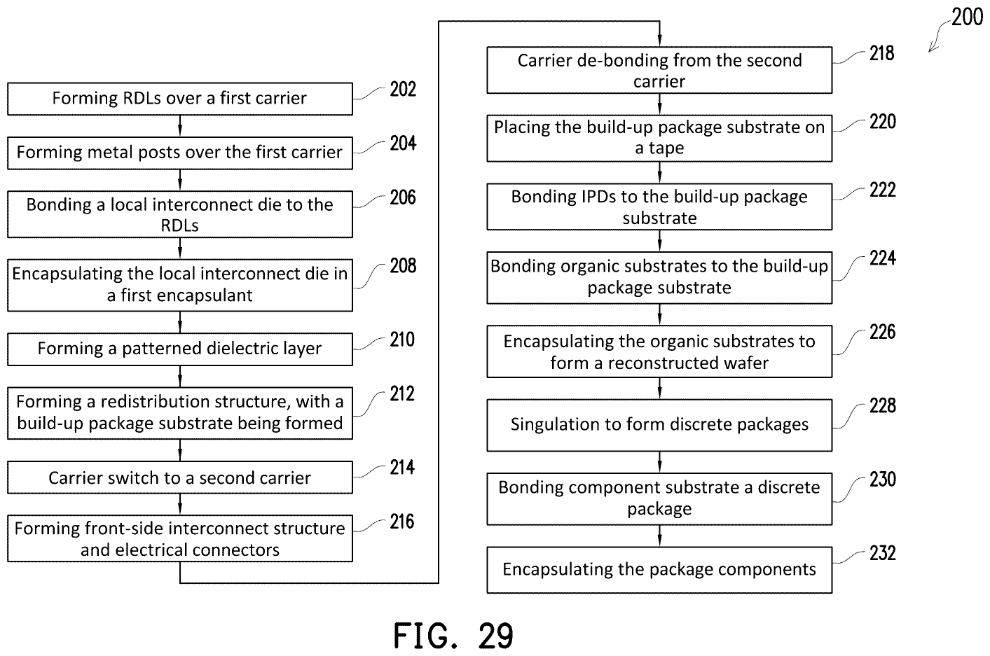

FIGS. 1 through 16 illustrate the cross-sectional views of intermediate stages in the formation of a package including an interconnect die in accordance with some embodiments. The corresponding processes are also reflected schematically in the process flow shown in FIG. 29.

Referring to FIG. 1, carrier 20 is provided, and release film 22 is coated on carrier 20. Carrier 20 is formed of a transparent material, and may be a glass carrier, a ceramic carrier, or the like. Release film 22 may be formed of a Light-To-Heat-Conversion (LTHC) coating material. Release film 22 may be applied onto carrier 20 through coating. In accordance with some embodiments, the LTHC coating material is capable of being decomposed under the heat of light/radiation (such as laser), and hence can release carrier 20 from the structure formed thereon.

In accordance with some embodiments, as shown in FIG. 1, dielectric layer 24 is formed on release film 22. Dielectric layer 24 may be formed of or comprise a polymer, which may be a photo-sensitive polymer such as polybenzoxazole (PBO), polyimide, benzocyclobutene (BCB), or the like.

Redistribution Lines (RDLs) 26 are then formed. RDLs 26 include via portions extending into dielectric layer 24, and trace portions over dielectric layer 24. The respective process is illustrated as process 202 in the process flow 200 as shown in FIG. 29. The formation of RDLs 26 may include patterning dielectric layer 24 to form openings (occupied by the via portions), and depositing a metal seed layer. The metal seed layer includes some portions over dielectric layer 24, and some portions extending into dielectric layer 24. In accordance with some embodiments, the metal seed layer includes a titanium layer and a copper layer over the titanium layer. The metal seed layer may be formed, for example, using Physical Vapor Deposition (PVD), Chemical Vapor Deposition (CVD), or the like. Next, a plating mask (not shown) is applied and patterned, with openings formed therein, through which some portions of metal seed layer are exposed. The patterned plating mask may include a photoresist. A metallic material is then deposited on the exposed portions of the metal seed layer, followed by the removal of the plating mask to expose the underlying portions of the metal seed layer. The metallic material may include Cu, Al, Ti, W, Au, or the like. The exposed portions of the metal seed layer are then removed, leaving RDLs 26. It is appreciated that although the via portions and the trace portions of RDLs 26 are illustrated as having interfaces therebetween, there may not be interfaces when the above-recited processes are adopted.

After the formation of RDLs 26, metal posts 28 may be formed. The respective process is illustrated as process 204 in the process flow 200 as shown in FIG. 29. It is appreciated that although one RDL layer is shown as an example, more layers (such as 2, 3, 4 or more layers) of RDLs may be formed before the formation of metal posts 28, depend in the routing requirement. The formation of metal posts 28 may include depositing a metal seed layer over RDLs 26, and forming a patterned plating mask, through which some portions of the metal seed layer are exposed. A plating process is then performed to plate a metallic material into the openings in the plating mask. The plating mask is then removed, followed by the etching of the exposed portions of the metal seed layer to form metal posts 28.

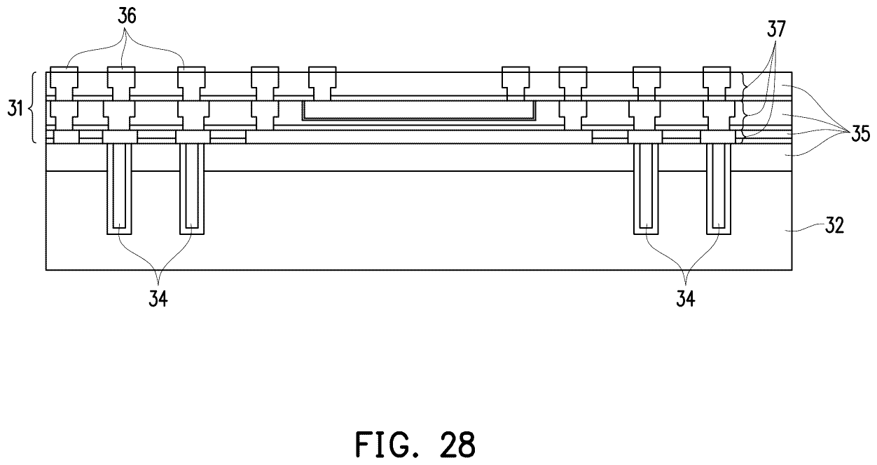

FIG. 2 illustrates the bonding of interconnect die 30 to RDLs 26. The respective process is illustrated as process 206 in the process flow 200 as shown in FIG. 29. Although one interconnect die 30 is illustrated, there may be a plurality of interconnect dies 30 being bonded. The plurality of interconnect dies 30 may have the identical structure or different structures. Interconnect die 30 is illustrated schematically, and the detailed structure is shown in FIG. 28 in accordance with some embodiments.

FIG. 28 illustrates an example interconnect die 30 in accordance with some embodiments. Interconnect die 30 includes substrate 32, which may be a semiconductor substrate such as a silicon substrate. Substrate 32 may also be a dielectric substrate, which is formed of a dielectric material such as silicon oxide, silicon nitride, or the like. In accordance with some embodiments, there is no through-via formed to penetrate through substrate 32, regardless of whether substrate 32 is formed of a semiconductor or a dielectric material. In accordance with alternative embodiments, through-vias 34 are formed to extend into substrate 32. Accordingly, through-vias 34 are shown using dashed lines to indicate that through-vias 34 may or may not be formed.

In accordance with some embodiments, interconnect die 30 is free from active devices such as transistors and diodes therein. Interconnect die 30 may or may not be free from passive devices such as capacitors, transformers, inductors, resistors, and the like. In accordance with alternative embodiments of the present disclosure, interconnect die 30 include some active devices and/or passive devices (not shown), and the active devices may be formed at the top surfaces of semiconductor substrate 32.

Interconnect die 30 further includes interconnect structure 31 over substrate 32. Interconnect structure 31 further includes dielectric layers 35 and metal lines and vias 37 in the dielectric layers. The dielectric layers 35 may include Inter-Metal Dielectric (IMD) layers. In accordance with some embodiments, some of the dielectric layers 35 (such as lower dielectric layers 35) are formed of low-k dielectric materials having dielectric constant values (k-value) lower than 3.8, and the k-values may be lower than about 3.0 or about 2.5. The low-k dielectric layers 35 may be formed of a carbon-containing low-k dielectric material, Hydrogen SilsesQuioxane (HSQ), MethylSilsesQuioxane (MSQ), or the like. The formation of metal lines and vias 37 may include single damascene and dual damascene processes. Bond structures 36 such as metal pillars or metal pads are formed at the surface of interconnect die 30.

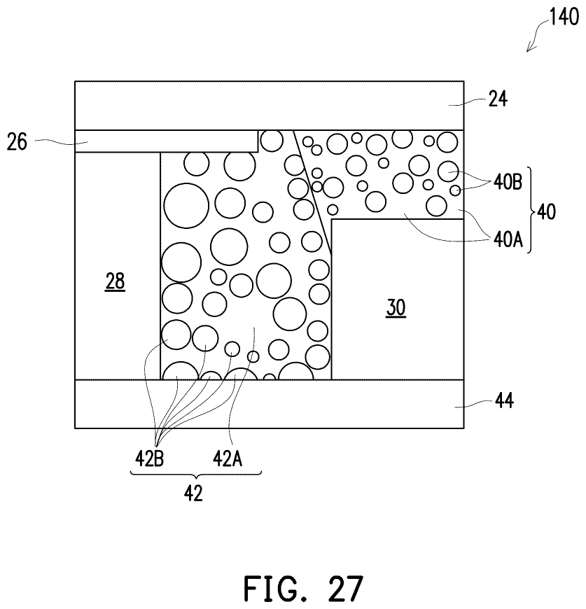

Referring back to FIG. 2, in accordance with some embodiments, the bonding of interconnect die 30 to RDLs 26 may be through solder bonding or metal-to-metal direct bonding. For example, the bonding may be performed through solder regions 38. After the bonding, underfill 40 is dispensed into the gap between interconnect die 30 and the underlying RDLs 26. The gap may have height H1 in the range between about 10 μm and about 30 μm. In accordance with some embodiments, underfill 40 may include a base material 40A (FIG. 27), which may include a polymer, a resin, an epoxy, and/or the like, and filler particles 40B in the base material 40A. The filler particles 40B may be dielectric particles of silica, alumina, boron nitride, or the like, and may have spherical shapes.

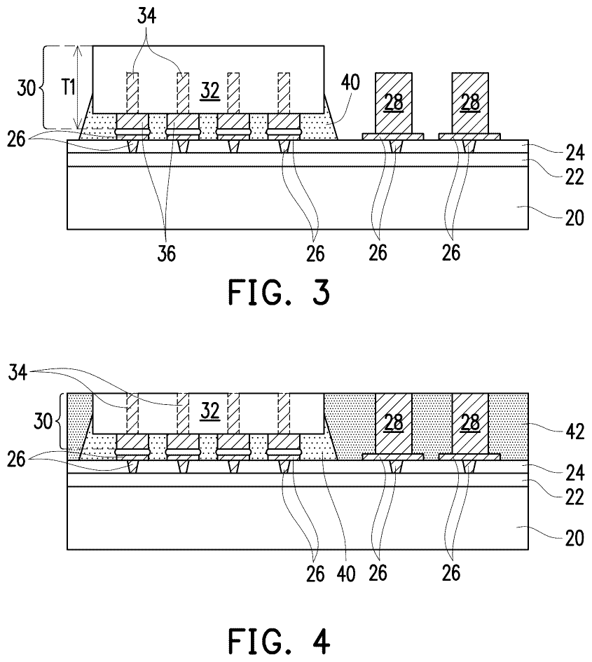

Referring to FIG. 3, a thinning process is performed to thin substrate 32 in interconnect die 30. The remaining substrate 32 may have thickness T1 smaller than about 200 μm. Thickness T1 may also be in the range between about 100 μm and about 200 μm. The thinning process may reduce the aspect ratio of the gaps between neighboring interconnect dies 30 and metal posts 28.

Next, encapsulant 42 is dispensed to encapsulate interconnect die 30 and metal posts 28 therein, as shown in FIG. 4. The respective process is illustrated as process 208 in the process flow 200 as shown in FIG. 29. Encapsulant 42 fills the gaps between neighboring metal posts 28 and the gaps between metal posts 28 and interconnect die 30. Encapsulant 42 may include a molding compound, a molding underfill, an epoxy, and/or a resin. When the encapsulation is finished, the top surface of encapsulant 42 is higher than the top ends of metal posts 28 and the top surfaces of interconnect die 30. Encapsulant 42 may include a base material 42A (FIG. 27), which may be a polymer, a resin, an epoxy, or the like, and filler particles 42B in the base material. The filler particles 42B may be dielectric particles of silica, alumina, boron nitride, or the like, and may have spherical shapes.

A planarization process such as a Chemical Mechanical Polish (CMP) process or a mechanical grinding process is then performed to thin encapsulant 42 and interconnect die 30, until metal posts 28 are revealed. Metal posts 28 are alternatively referred to as through-vias 28 hereinafter since they penetrate through encapsulant 42. In accordance with some embodiments in which interconnect die 30 includes through-vias 34, through-vias 34 are also revealed by the planarization process.

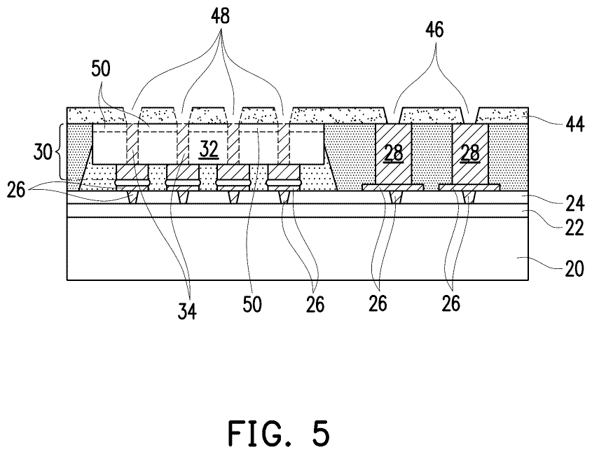

FIG. 5 illustrates the formation of patterned dielectric layer 44 in accordance with some embodiments. The respective process is illustrated as process 210 in the process flow 200 as shown in FIG. 29. Dielectric layer 44 may be or may comprise an organic material such as a polymer, which may be a photo-sensitive polymer such as PBO, polyimide, or the like. Dielectric layer 44 may also be formed of or comprise an inorganic material such as silicon oxide, silicon nitride, or the like.

Dielectric layer 44 is patterned to form openings 46, with through-vias 28 being exposed through openings 46. In accordance with some embodiments in which through-vias 34 are formed, openings 48 are also formed to reveal through-vias 34. Otherwise, openings 48 are not formed. Also, when through-vias 34 are formed, dielectric layer 50 may be (or may not be) formed in interconnect die 30, with dielectric layer 50 contacting the back surface of semiconductor substrate 32. dielectric layer 50 may be formed of or comprise silicon oxide, silicon nitride, or the like.

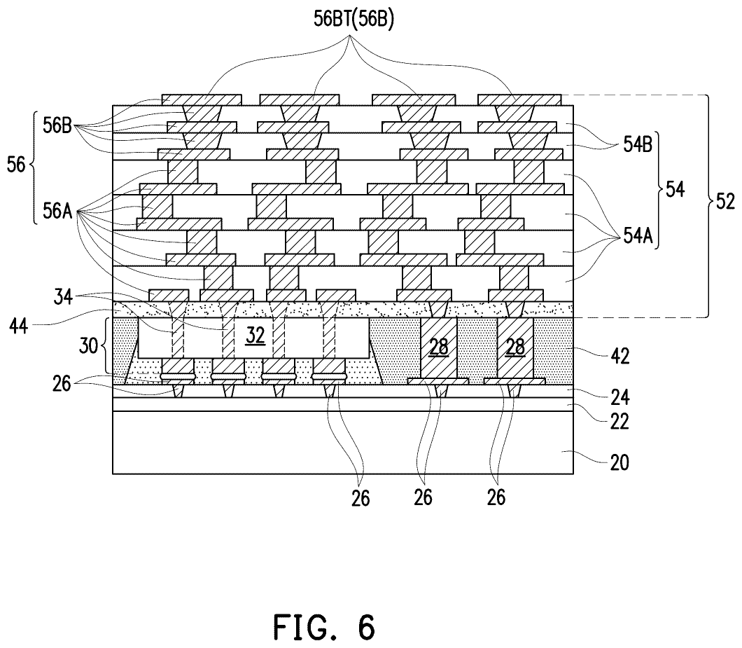

FIG. 6 illustrates the formation of redistribution structure 52 over interconnect die 30. The respective process is illustrated as process 212 in the process flow 200 as shown in FIG. 29. In accordance with some embodiments, redistribution structure 52 includes dielectric layers 54A and dielectric layers 54B over dielectric layers 54A. Dielectric layers 54A and dielectric layers 54B may be formed of different materials and have different thicknesses. For example, each of the dielectric layers 54A may be thicker than any of the dielectric layers 54B. In accordance with some embodiments, dielectric layers 54A are formed of a non-photo-sensitive material such as molding compound, molding underfill, silicon oxide, silicon nitride, or the like. Dielectric layers 54B, on the other hand, may be formed of a photo-sensitive material(s) such as PBO, polyimide, BCB, or the like. In accordance with alternative embodiments, both of dielectric layers 54A and 54B are formed of photo-sensitive material(s).

RDLs 56A are formed in dielectric layers 54A, and RDLs 56B are formed in dielectric layers 54B. In accordance with some embodiments, RDLs 56A are thicker and/or wider than RDLs 56B, and may be used for long-range electrical routing, while RDLs 56B may be used for short-range electrical routing. RDLs 56A and 56B are electrically connected to through-vias 28 and through-vias 34 (when formed). Some surface conductive features 56BT are formed, which may be parts of RDLs 56B, or may be separately formed Under-Bump Metallurgies (UBMs).

In accordance with some embodiments, RDLs 56A and 56B are electrically connected to RDLs 26 through through-vias 28. In accordance with alternative embodiments, through-vias 28 are not formed. Accordingly, all of the connection of RDLs 56A and 56B to RDLs 26 are made through through-vias 34 in interconnect die 30. Since through-vias 34 may be formed smaller than through-vias 28, more interconnection can be made. In accordance with yet alternative embodiments, the interconnection of RDLs 56A and 56B to RDLs 26 are made through both of through-vias 34 in interconnect die 30 and through-vias 28.

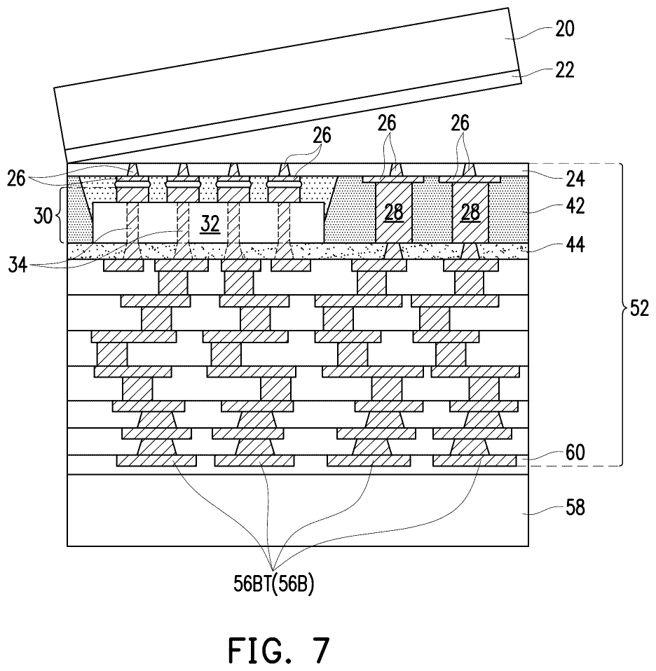

In a subsequent process, as show in FIG. 7, a carrier-switch process is performed. The respective process is illustrated as process 214 in the process flow 200 as shown in FIG. 29. In the carrier-switch process, redistribution structure 52 is first attached to carrier 58 through release film 60. Carrier 58 is formed of a transparent material, and may be a glass carrier, a ceramic carrier, or the like. Release film 60 may be formed of an LTHC coating material. Carrier 20 is then de-bonded from redistribution structure 52. In the de-bonding process, a light beam (which may be a laser beam) is projected on release film 22, and the light beam penetrates through the transparent carrier 20. Release film 22 is thus decomposed. Carrier 20 may be lifted off from release film 22, and hence redistribution structure 52 (along with interconnect die 30) is de-bonded (demounted) from carrier 20.

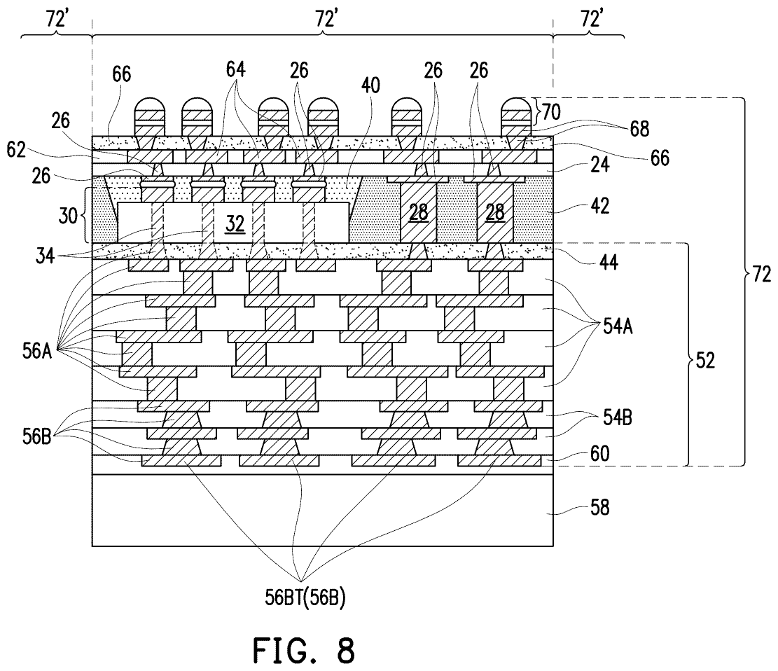

FIG. 8 illustrates the formation of a front-side interconnect structure and electrical connectors, which are overlying and connecting to redistribution structure 52. The respective process is illustrated as process 216 in the process flow 200 as shown in FIG. 29. The front-side interconnect structure includes dielectric layer(s) 62 and RDLs 64 in dielectric layers 62. In accordance with some embodiments, dielectric layer 62 is formed of or comprises a polymer such as PBO, polyimide, BCB, or the like. The formation process includes coating dielectric layer 62 in a flowable form, and then curing dielectric layer 62. In accordance with alternative embodiments of the present disclosure, dielectric layers 62 is formed of an inorganic dielectric material such as silicon nitride, silicon oxide, or the like. The formation method may include CVD, Atomic Layer Deposition (ALD), Plasma-Enhanced Chemical Vapor Deposition (PECVD), or another applicable deposition method. The formation of RDLs 64 may be similar to the formation of RDLs 26, and the details are not repeated herein.

FIG. 8 further illustrates the formation of dielectric layer 66, UBMs 68, and electrical connectors 70 in accordance with some embodiments. Dielectric layer 66 may also be formed of a polymer such as polyimide, PBO, or the like. UBMs 68 extend into dielectric layer 66. To form UBMs 68, openings are formed in dielectric layer 66 to expose the underlying metal pads, which are parts of RDLs 64. UBMs 68 are then formed through a deposition process such as a PVD process. UBMs 68 may be formed of or comprise nickel, copper, titanium, or multi-layers thereof.

Electrical connectors 70 are then formed on UBMs 68. The formation of electrical connectors 70 may include placing solder balls on the exposed portions of UBMs 68, and then reflowing the solder balls, and hence electrical connectors 70 are solder regions. In accordance with alternative embodiments of the present disclosure, the formation of electrical connectors 70 includes performing a plating process to form solder layers, and then reflowing the solder layers. Electrical connectors 70 may also include non-solder metal pillars, or may have composite structures including metal pillars and solder caps over the non-solder metal pillars, which may also be formed through plating. Throughout the description, the structure over release film 60 is referred to as build-up package substrate 72. Build-up package substrate 72 may be a wafer-level package component including a plurality of identical build-up package substrates 72′ therein.

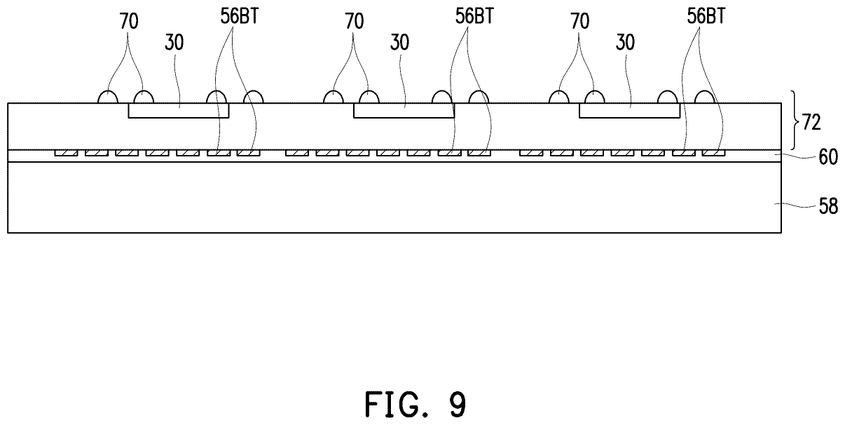

FIGS. 9 through 14 illustrate the formation of packages by bonding package components to the opposite sides of build-up package substrate 72. In these figures, the details of build-up package substrate 72 are not shown, while the details may be found referring to the preceding figures. The surface conductive features 56BT, interconnect dies 30, and electrical connectors 70 are illustrated schematically to illustrate the front side (the side having electrical connectors 70) and the back side (the side having conductive features 56BT) of build-up package substrate 72. FIG. 9 illustrates the simplified view of the structure shown in FIG. 8, with the details in build-up package substrate 72 not shown.

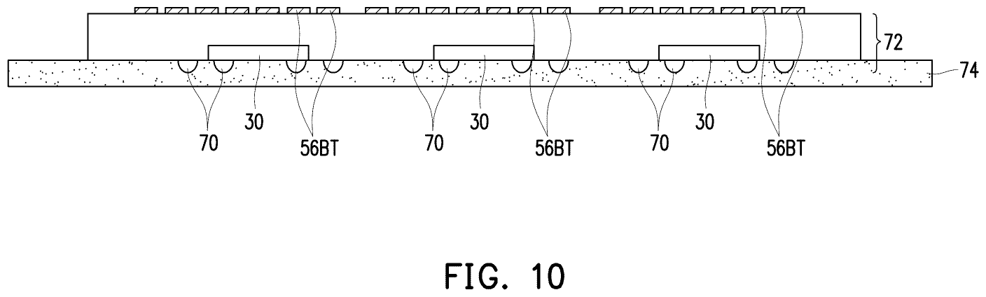

Next, build-up package substrate 72 is de-bonded (demounted) from carrier 58. The respective process is illustrated as process 218 in the process flow 200 as shown in FIG. 29. The de-bonding may be performed, for example, by projecting a light beam (which may be a laser beam) on release film 60, and the light beam penetrates through the transparent carrier 58. Release film 60 is thus decomposed. Carrier 58 is lifted off from release film 60, and hence build-up package substrate 72 is de-bonded (demounted) from carrier 58. Build-up package substrate 72 is then placed on tape 74, which may be fixed on a frame (not shown). The resulting structure is shown in FIG. 10. The respective process is illustrated as process 220 in the process flow 200 as shown in FIG. 29. The side of electrical connectors 70 faces, and may be in contact with, tape 74. Conductive features 56BT are exposed.

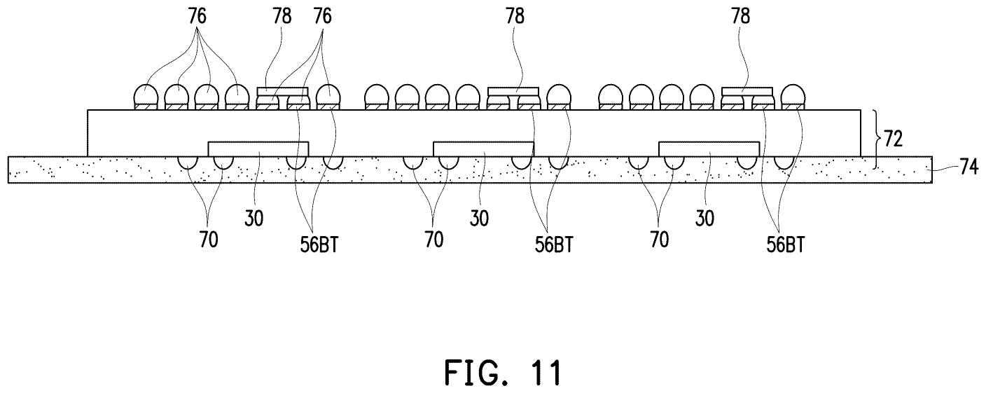

Referring to FIG. 11, solder regions 76 are formed on conductive features 56BT, which may be metal pads, metal pillars, UBMs, or the like. Solder regions 76 are reflowed. Next, device dies 78 are bonded to build-up package substrate 72 through some of solder regions 76. In accordance with some embodiments, device dies 78 are Integrated Passive Device (IPD) dies, which may include passive devices therein. The respective process is illustrated as process 222 in the process flow 200 as shown in FIG. 29. The passive devices may include capacitors, resistors, inductors, and/or the like. In accordance with alternative embodiments, device dies 78 may include active devices.

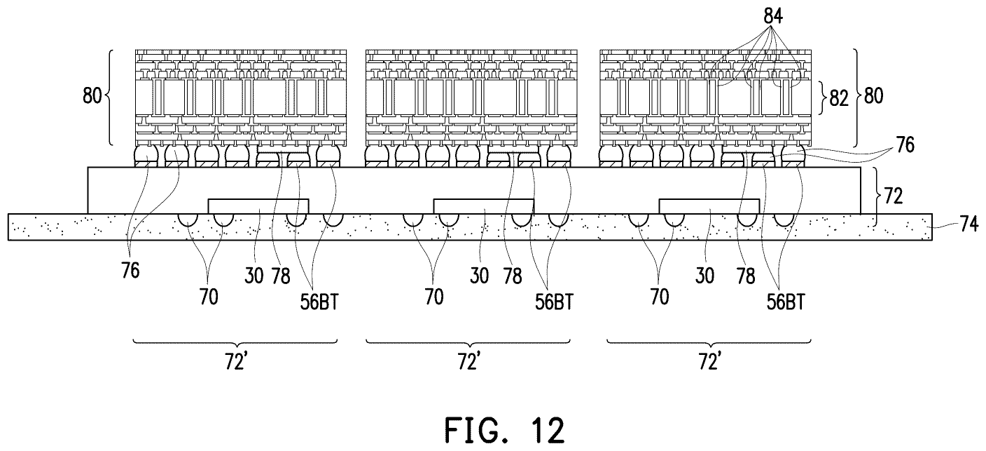

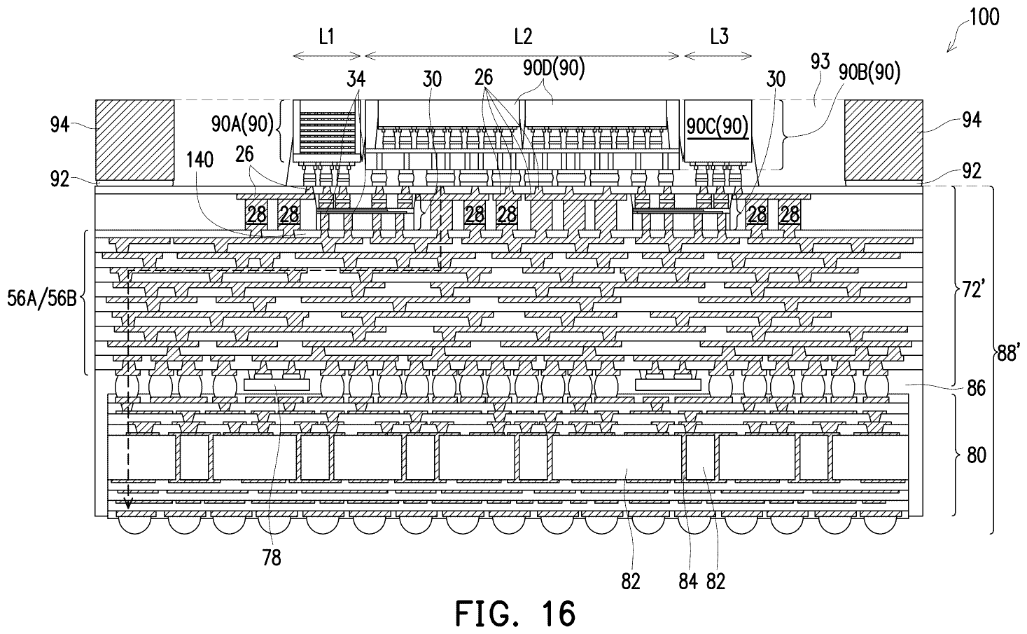

FIG. 12 illustrates the bonding of package substrates 80 to the build-up package substrates 72′ in build-up package substrate 72 therein. The respective process is illustrated as process 224 in the process flow 200 as shown in FIG. 29. Package substrates 80 may include organic dielectric layers, and are sometimes referred to as organic package substrates. Package substrates 80 may be cored package substrates including cores, or may be core-less package substrates that do not have cores therein. For example, package substrates 80 may include dielectric core 82 (also refer to FIG. 16), and Plating Through-Holes (PTHs, which are conductive pipes) 84 therein. In accordance with alternative embodiments, package substrates 80 are in an un-sawed wafer, and are bonded to build-up package substrate 72 through wafer-to-wafer bonding. Package substrates 80 are free from active devices such as transistors and diodes therein. The bonding may be achieved through solder regions 76. The back surfaces (the illustrated bottom surfaces) of device dies 78 may be spaced apart from, or may be in contact with, the corresponding underlying build-up package substrates 72′.

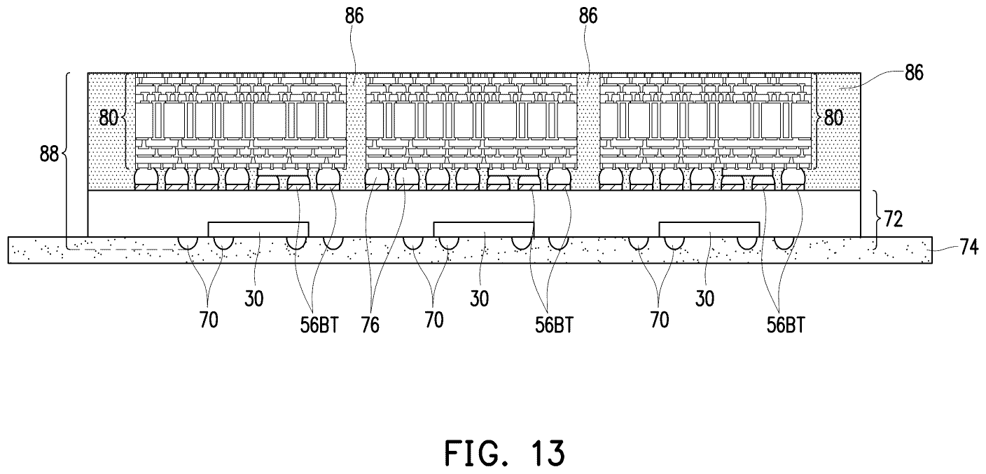

Referring to FIG. 13, encapsulant 86 is dispensed to encapsulate package substrates 80 therein. The respective process is illustrated as process 226 in the process flow 200 as shown in FIG. 29. Encapsulant 86 fills the gaps between neighboring package substrates 80. Encapsulant 86 may include a molding underfill, which is also filled into the gaps between build-up package substrate 72 and the overlying package substrates 80. In accordance with alternative embodiments, an underfill (not shown) may be dispensed to fill the gaps between build-up package substrate 72 and the overlying package substrates 80, followed by the dispensing of encapsulant 86, which may include a molding compound. Encapsulant 86 may include a base material, which may be a polymer, a resin, an epoxy, or the like, and filler particles in the base material. The filler particles may be dielectric particles of silica, alumina, boron nitride, or the like, and may have spherical shapes. Throughout the description, the structure over tape 74 is referred to as reconstructed wafer 88.

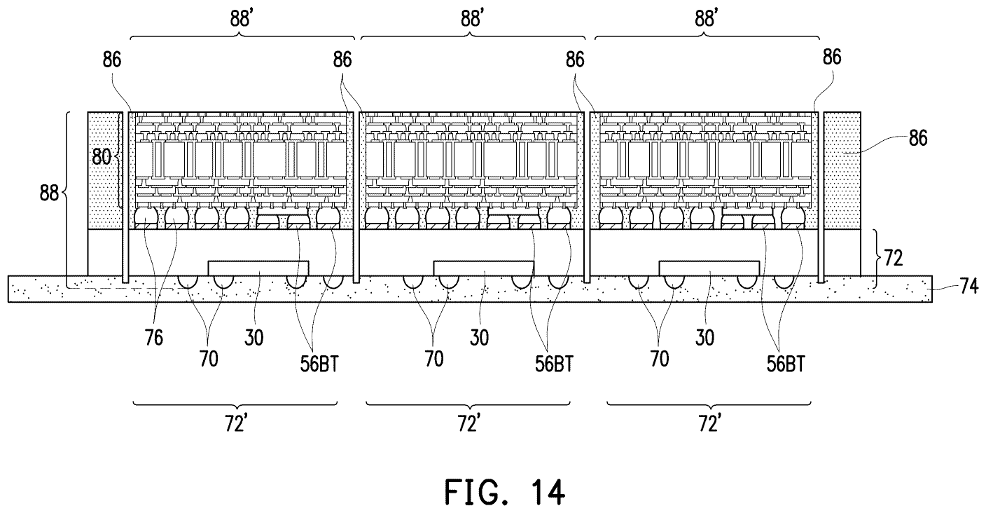

FIG. 14 illustrates a singulation process for separating reconstructed wafer 88 into discrete package components 88′. The respective process is illustrated as process 228 in the process flow 200 as shown in FIG. 29. Package components 88′ are also referred to as compound package substrates 88′ since they include two types of package substrates, build-up package substrates 72′ and package substrates 80. The build-up package substrates 72′ and the corresponding package substrates 80 in combination function as integrated package substrates. The singulation process may be performed using a blade, or through a laser ablation process. In each of package components 88′, encapsulant 86 may encircle package substrate 80.

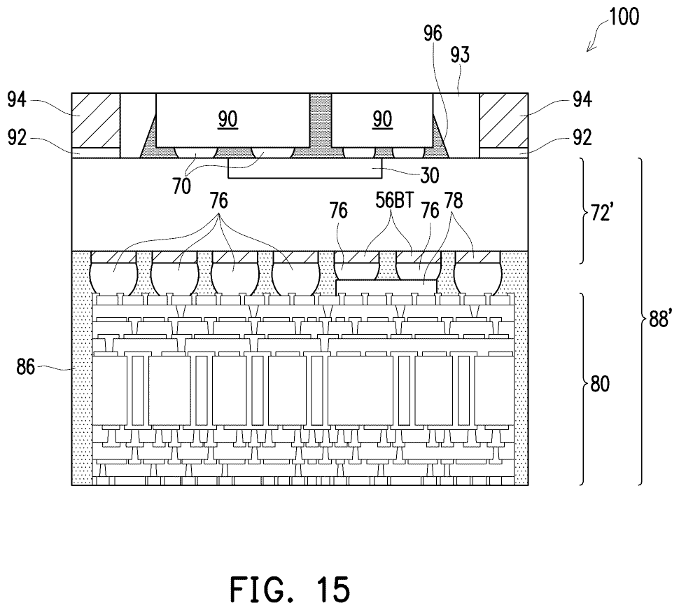

Referring to FIG. 15, a plurality of package components 90 are bonded to compound package substrate 88′. Package 100 is thus formed. The respective process is illustrated as process 230 in the process flow 200 as shown in FIG. 29. In accordance with some embodiments, package components 90 include a logic die, which may be a Central Processing Unit (CPU) die, a Graphic Processing Unit (GPU) die, a mobile application die, a Micro Control Unit (MCU) die, an input-output (IO) die, a BaseBand (BB) die, an Application processor (AP) die, or the like. Package components 90 may also include a memory die(s) such as Dynamic Random-Access Memory (DRAM) dies, Static Random-Access Memory (SRAM) dies, or the like. The memory dies may be discrete memory dies, or may be in the form of a die stack that includes a plurality of stacked memory dies. Package components 90 may also include System-on-Chip (SOC) dies.

Next, underfill 96 is dispensed into the gap between package components 90 and the underlying build-up package substrate 72′. In accordance with some embodiments, stiffener ring 94 is adhered to build-up package substrate 72′ through adhesive films 92. Stiffener ring 94 has the function of reducing the warpage of the resulting package 100.

In accordance with some embodiments, package components 90 are encapsulated in encapsulant 93. The respective process is illustrated as process 232 in the process flow 200 as shown in FIG. 29. In accordance with alternative embodiments, no encapsulant is used to encapsulate package components 90. Encapsulant 93 is thus shown as being dashed to indicate that it may or may not be formed.

FIG. 16 illustrates a detailed view of package 100 as shown in FIG. 15 in accordance with some embodiments. In package 100, compound package substrate 88′ includes build-up package substrate 72′ and package substrate 80 bonded to each other. IPD dies 78 may be bonded between build-up package substrate 72′ and package substrate 80. Package substrate 80 is encapsulated in encapsulant 86. Alternatively stated, a part of compound package substrate 88′ is encapsulated in encapsulant 86, while another part (build-up package substrate 72′) of compound package substrate 88′ is outside of encapsulant 86.

In accordance with some embodiments, the package components 90 include HBM 90A, package 90B, and device die 90C. Package 90B may also include interposer 104′ and device dies 90D (also referred to as package components 90D) bonding to interposer 104′. Each of HBM 90A, package 90B, and device die 90C are bonded to build-up package substrate 72′ directly.

In accordance with some embodiments, interconnect dies 30 are embedded in the build-up package substrate 72′. Interconnect dies 30 are used to electrically and signally interconnect package components 90. Embedding interconnect dies 30 inside build-up package substrate 72′ has some advantageous features. For example, if interconnect dies 30 are built outside of build-up package substrate 72′, interconnect dies 30 will be built in the package 90B, in which package components 90 are located. The package components 90 (including UBMs 90A and package components 90D) that are to be electrically interconnected through the interconnect dies 30 will be at the same level, and in the same package. The package including the interconnect dies 30 and package components 90A and 90D thus will have a large size. The warpage of the resulting package will be increased. The yield of the bonding will be degraded due to the significant warpage of the large package components.

As a comparison, when interconnect dies 30 are built in build-up package substrate 72′ in accordance with the embodiments of the present disclosure, package components 90A and 90B may be bonded to the underlying build-up package substrate 72′ as discrete device dies and small packages. For example, FIG. 16 illustrates that there are three discrete package components 90A, 90B, and 90C individually bonded to build-up package substrate 72′. Since the individual package components are smaller, the bonding yield is improved.

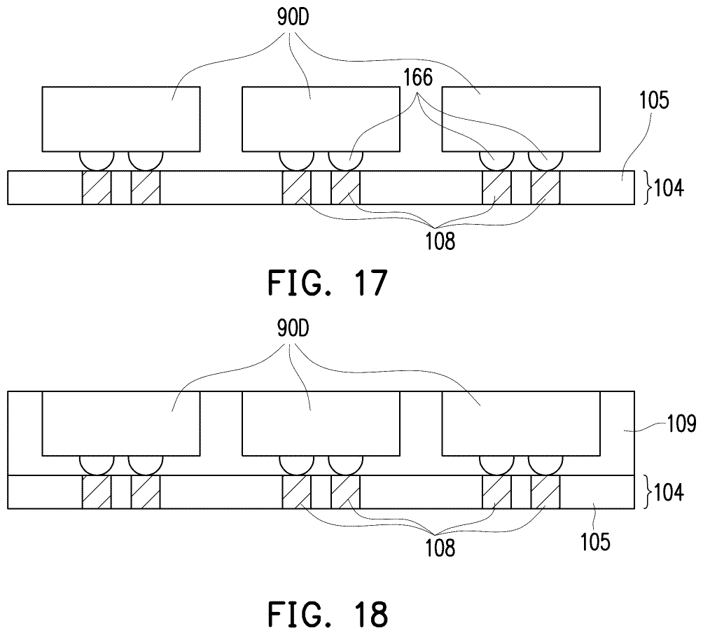

FIGS. 17-19 illustrate the formation of package components 90B (as shown in FIG. 16) in accordance with some embodiments. Referring to FIG. 17, device dies 90D are bonded to interposer wafer 104. Device dies 90D may include active dies including active devices, passive dies including passive devices, and/or the like. In accordance with some embodiments, the bonding is performed through solder regions 106. Alternatively, metal-to-metal direct bonding, hybrid bonding, and the like may also be used. In accordance with some embodiments, interposer wafer 104 includes a semiconductor substrate 105, and through-vias 108 penetrating through semiconductor substrate 105. The details of interposer wafer 104 are not shown. For example, redistribution structures (not shown), which include metal lines, are formed on opposite sides of semiconductor substrate 105, and are interconnected through through-vias 108. Interposer wafer 104 may also include solder regions (not shown) at the bottom surface.

Next, as shown in FIG. 18, encapsulant 109 is dispensed, and is then planarized. Device dies 90D may be revealed after the planarization process. In accordance with some embodiments, encapsulant 109 includes a molding underfill, which fills the gaps between device dies 90D and interposer wafer 104, and also fills the gaps between neighboring device dies 90D. In accordance with alternative embodiments, an underfill (not shown) may be dispensed to fill the gaps between device dies 90D and interposer wafer 104, followed by the dispensing of a molding compound.

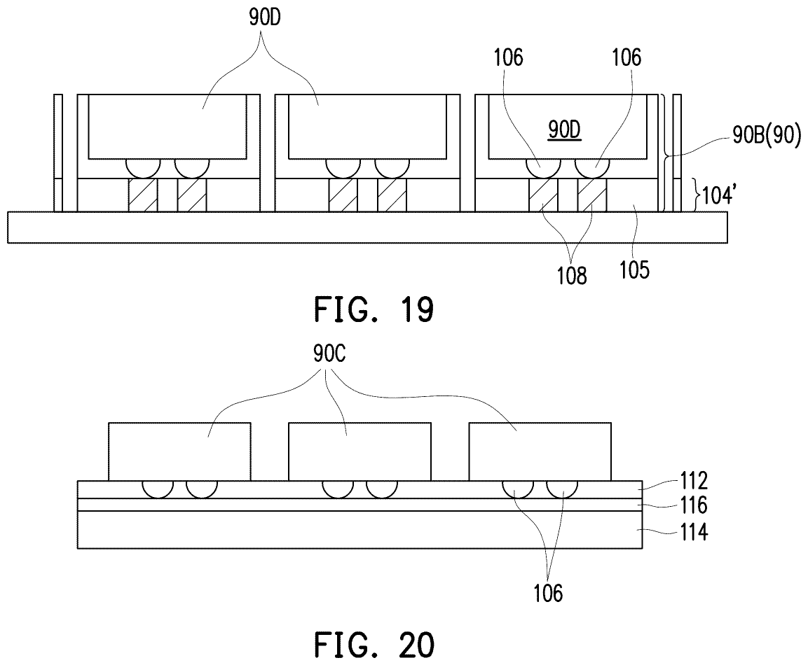

FIG. 19 illustrates a singulation process, wherein encapsulant 109 and interposer wafer 104 are sawed-through to form individual package components 90B, which are sometimes referred to as Chip-on-Wafer (CoW) packages. Each of package components 90B may include a plurality of device dies 90D bonded to the same interposer 104′, which is a piece of the sawed interposer wafer 104. Package components 90B may then be used in the package 100 as shown in FIGS. 15 and 16.

FIGS. 20-22 illustrate the formation of package components 90E in accordance with some embodiments. In accordance with some embodiments, Non-Conductive Film (NCF) 112 is attached (laminated) over carrier 114, for example, through release film 116. In accordance with some embodiments, NCF 112 is a pre-formed solid (and flexible) film, which is adhered onto wafer release film 116. The electrical connectors 106 of device dies 90C may be pressed into and penetrate through NCF 112. In accordance with alternative embodiments, NCF 112 is dispensed onto wafer 20 as a flowable material, and is then cured as a solid film.

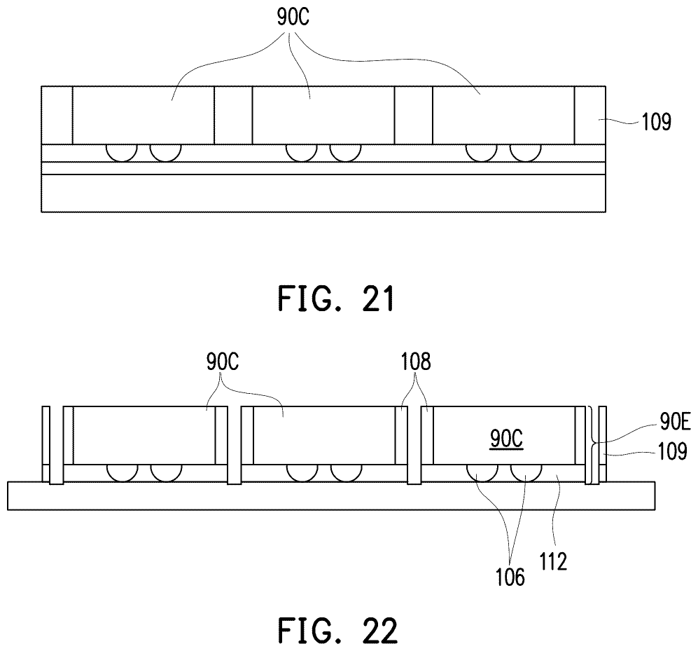

Next, as shown in FIG. 21, encapsulant 109 is dispensed, and is then planarized. Device dies 90C may be revealed after the planarization process. In accordance with some embodiments, encapsulant 109 includes a molding underfill, a molding compound, or the like.

FIG. 22 illustrates a singulation process, wherein encapsulant 109 and NCF 112 are sawed-through to form individual package components 90E. Package components 90E may then be used in the package 100 as shown in FIGS. 15 and 16. For example, package components 90E may replace any of package components 90A, 90B, and 90C.

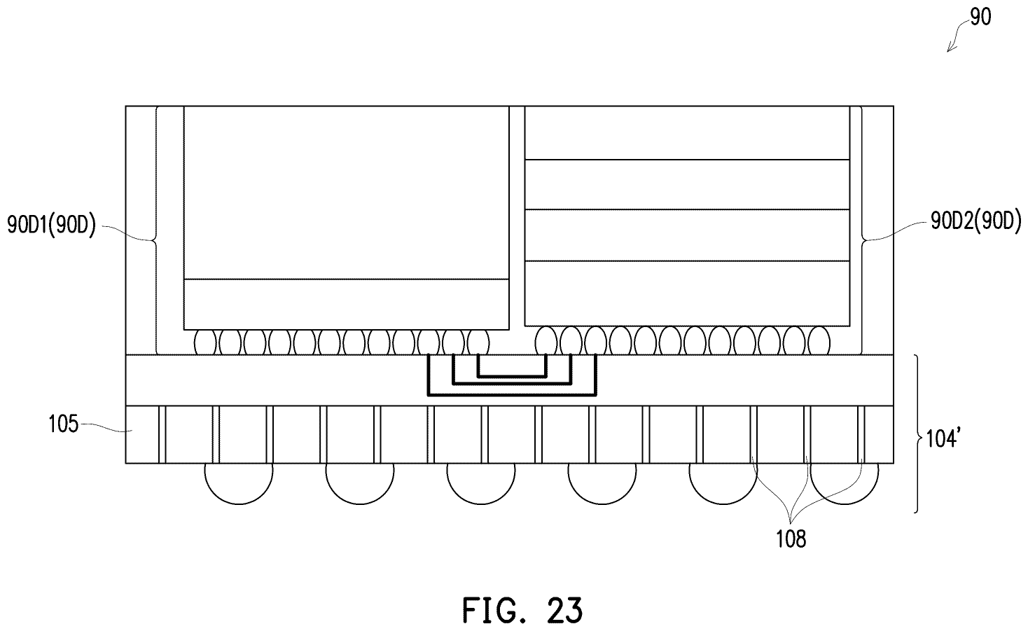

Package components 90 may also be in other forms. For example, FIGS. 23 through 26 illustrate some example package components 90 in accordance with some embodiments. FIG. 23 illustrates a CoW package 90 in accordance with some embodiments. These embodiments are also illustrated in the processes shown in FIGS. 17 through 19. CoW package 90 thus includes interposer 104′ and package components 90D bonded to interposer 104′. In accordance with some embodiments, package components 90D include logic dies 90D1 such as CPU, GPU, or the like, and HBM 90D2.

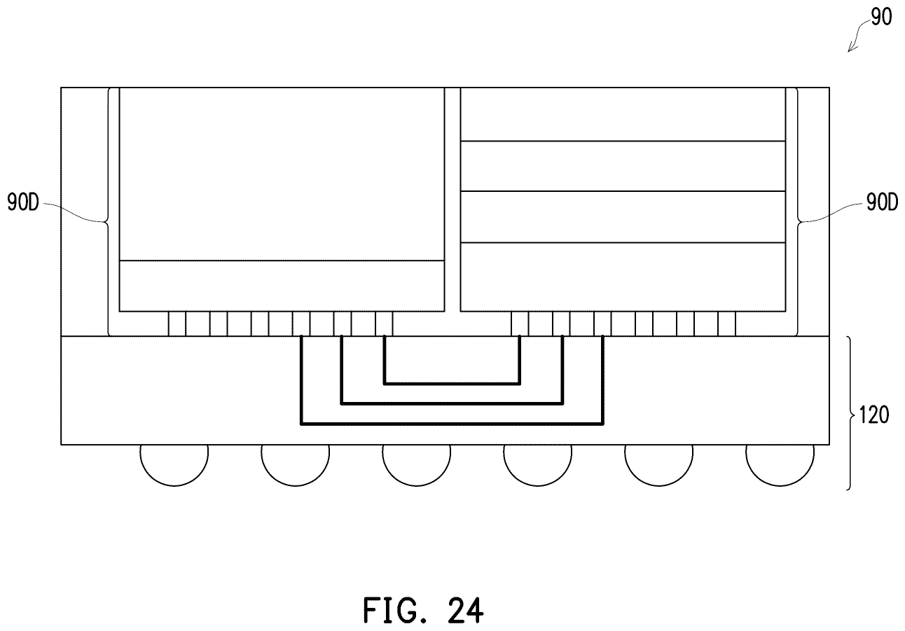

FIG. 24 illustrates an Integrated Fanout (InFO) package 90 in accordance with some embodiments. In accordance with these embodiments, fan-out redistribution structure 120 is formed layer-by-layer starting from package components 90D. Redistribution structure 120 includes a plurality of RDLs therein, which may interconnect package components 90D.

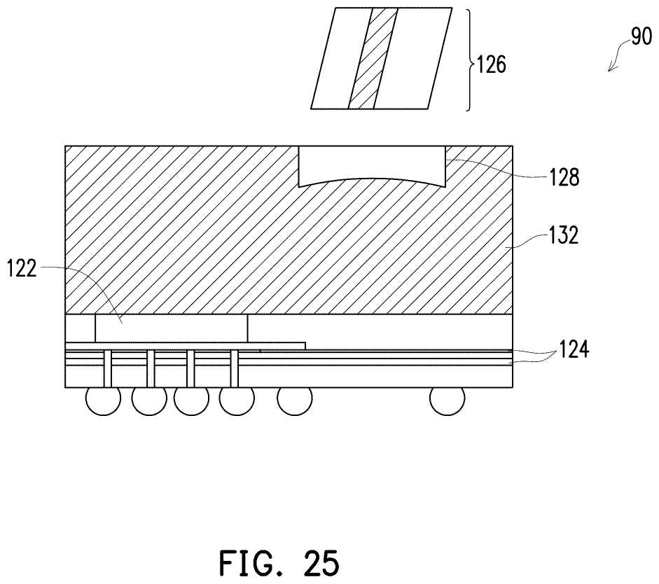

FIG. 25 illustrates an example package component 90 in accordance with alternative embodiments, wherein package component 90 includes an optical device die. In accordance with some embodiments, optical device die 90 includes devices 122, which may include electrical-to-optical converters and/or optical-to-electrical converters such as image sensors, grating coupler, and the like. Optical device die 90 may also include waveguides 124. Also, micro-lens 128 may be formed in semiconductor substrate 132. Optical fiber 126 may be attached to package component 90, and aligned to micro-lens 128.

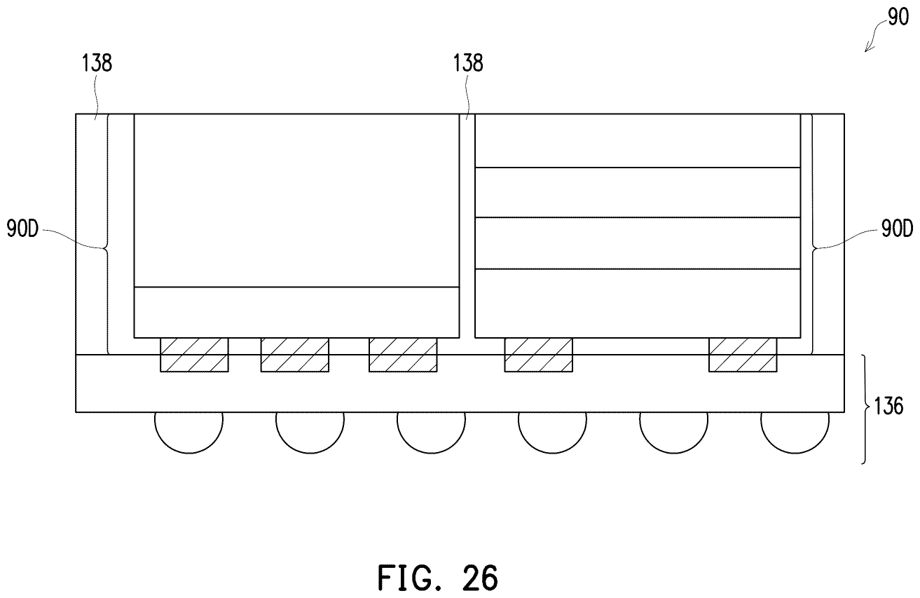

FIG. 26 illustrates package component 90 formed through hybrid bonding in accordance with some embodiments. Device dies or packages 90D may be bonded to device die 136 through hybrid bonding, direct metal-to-metal bonding, or the like. Gap-filling material 138 is formed to fill the gap between package components 90D. Gap-filling material 138 may be formed of or comprises a silicon nitride etch stop layer and an oxide filling material. In accordance with alternative embodiments, gap-filling material 138 may comprise a molding compound, a molding underfill, or the like.

FIG. 27 illustrates an amplified view of a portion 140 of the package 100 as shown in FIG. 16. Interconnect die 30 and dielectric layers 24 and 44 are illustrated. Encapsulant 42 may include base material 42A and filler particles 42B. Since encapsulant 42 is polished in the process shown in FIG. 4, some filler particles 42B are polished to form partial particles. The partial particles 42B may have planar bottom surfaces in contact with dielectric layer 44. As a comparison, the filler particles 80B in contact with dielectric layer 24, through-vias 28, and interconnect die 30 are full spherical particles that are not polished, and may have rounded top surfaces.

In above-illustrated embodiments, some processes and features are discussed in accordance with some embodiments to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By embedding the interconnect die in a build-up package substrate, package components (such as device dies and packages) may be directly bonded to the build-up package substrate, and may be electrically interconnected by the interconnect die. The size of the bonded package components thus may be reduced since they don't include the interconnect die therein. The sizes of the packages bonded to package substrates are thus reduced. The warpage of the resulting packages is reduced, and manufacturing yield is improved. Also, the insertion loss may be reduced.

In accordance with some embodiments, a method comprises forming a build-up package substrate comprising forming a first plurality of RDLs and a second plurality of RDLs over a carrier; forming a first plurality of through-vias on the first plurality of RDLs; bonding an interconnect die to the second plurality of RDLs; encapsulating the interconnect die and the first plurality of through-vias in a first encapsulant; and forming a third plurality of RDLs over the first encapsulant, wherein the third plurality of RDLs are electrically connected to the first plurality of through-vias; bonding an organic package substrate to the build-up package substrate, wherein the build-up package substrate and the organic package substrate in combination form a compound organic package substrate; and bonding a first package component and a second package component to the compound organic package substrate, wherein the first package component and the second package component are electrically interconnected through the interconnect die.

In an embodiment, the organic package substrate and the first package component are on opposite sides of the build-up package substrate. In an embodiment, the interconnect die comprises a low-k dielectric layer; and a metal line in the low-k dielectric layer, wherein the metal line electrically connects the first package component to the second package component. In an embodiment, the method further comprises after the organic package substrate is bonded to the build-up package substrate, encapsulating the organic package substrate in a second encapsulant. In an embodiment, the method further comprises, before the first package component and the second package component are bonded to the compound organic package substrate, sawing through the second encapsulant to separate the compound organic package substrate from other compound organic package substrates in the second encapsulant.

In an embodiment, the interconnect die comprises a second plurality of through-vias therein, and the method further comprises planarizing the first encapsulant to reveal the second plurality of through-vias, wherein the second plurality of through-vias electrically connect the first plurality of RDLs to the third plurality of RDLs. In an embodiment, the first package component and the second package component are bonded directly to the build-up package substrate. In an embodiment, the method further comprises, before the organic package substrate is bonded to the build-up package substrate, bonding a passive device die to the build-up package substrate, wherein the passive device die is between the organic package substrate and the build-up package substrate. In an embodiment, the interconnect die is free from active device therein. In an embodiment, the organic package substrate is a cored substrate comprising a dielectric core and conductive pipes in the dielectric core.

In accordance with some embodiments, a package comprises a build-up package substrate comprising a first plurality of RDLs; an interconnect die bonded to the first plurality of RDLs; a first encapsulant encapsulating the interconnect die therein; and a second plurality of RDLs on an opposite side of the first encapsulant than the first plurality of RDLs; a first package component and a second package component bonded to the build-up package substrate, wherein the first package component and the second package component are electrically interconnected through the interconnect die; and an organic package substrate bonded to the build-up package substrate. In an embodiment, the organic package substrate is bonded to the build-up package substrate through solder regions.

In an embodiment, the package further comprises a passive device die bonded to the build-up package substrate, wherein the passive device die is between the build-up package substrate and the organic package substrate. In an embodiment, the package further comprises a second encapsulant encapsulating the organic package substrate therein. In an embodiment, first sidewalls of the second encapsulant are vertically aligned to second sidewalls of the build-up package substrate. In an embodiment, the interconnect die comprises a low-k dielectric layer; and a metal line in the low-k dielectric layer, wherein the metal line electrically connects the first package component to the second package component. In an embodiment, the interconnect die comprises through-semiconductor vias therein, and wherein the first plurality of RDLs are electrically connected to the second plurality of RDLs through the through-semiconductor vias.

In accordance with some embodiments, a package comprises a build-up package substrate comprising an interconnect die; and a first encapsulant encapsulating the interconnect die therein; an organic package substrate bonded to the build-up package substrate; a second encapsulant encapsulating the organic package substrate therein, wherein first sidewalls of the build-up package substrate are flush with second sidewalls of the second encapsulant; and solder regions bonding the build-up package substrate to the organic package substrate, wherein the solder regions are in physical contact with both of the build-up package substrate and the organic package substrate. In an embodiment, the package further comprises a first package component and a second package component bonded to the build-up package substrate, wherein the first package component and the second package component are electrically interconnected through the interconnect die; and a underfill, wherein the underfill is in physical contact with each of the first package component, the second package component, and the build-up package substrate. In an embodiment, the package further comprises a third encapsulant encapsulating the first package component and the second package component therein.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package comprising:
a build-up package substrate comprising:
a first plurality of redistribution lines (RDLs);
an interconnect die bonded to the first plurality of RDLs;
a first encapsulant encapsulating the interconnect die therein; and
a second plurality of RDLs on an opposite side of the first encapsulant than the first plurality of RDLs;
a first package component and a second package component bonded to the build-up package substrate, wherein the first package component and the second package component are electrically interconnected through the interconnect die; and
an organic package substrate bonded to the build-up package substrate.

2. The package of claim 1, wherein the organic package substrate is bonded to the build-up package substrate through solder regions.

3. The package of claim 1 further comprising a passive device die bonded to the build-up package substrate, wherein the passive device die is between the build-up package substrate and the organic package substrate.

4. The package of claim 1 further comprising a second encapsulant encapsulating the organic package substrate therein.

5. The package of claim 4, wherein first sidewalls of the second encapsulant are vertically aligned to second sidewalls of the build-up package substrate.

6. The package of claim 1, wherein the interconnect die comprises: a low-k dielectric layer; and a metal line in the low-k dielectric layer, wherein the metal line electrically connects the first package component to the second package component.

7. The package of claim 1, wherein the interconnect die comprises through-semiconductor vias therein, and wherein the first plurality of RDLs are electrically connected to the second plurality of RDLs through the through-semiconductor vias.

8. A package comprising:
a build-up package substrate comprising:
an interconnect die; and
a first encapsulant encapsulating the interconnect die therein;
an organic package substrate bonded to the build-up package substrate;
a second encapsulant encapsulating the organic package substrate therein, wherein first sidewalls of the build-up package substrate are flush with second sidewalls of the second encapsulant; and
solder regions bonding the build-up package substrate to the organic package substrate, wherein the solder regions are in physical contact with both of the build-up package substrate and the organic package substrate.

9. The package of claim 8 further comprising:
a first package component and a second package component bonded to the build-up package substrate, wherein the first package component and the second package component are electrically interconnected through the interconnect die; and
a underfill, wherein the underfill is in physical contact with each of the first package component, the second package component, and the build-up package substrate.

10. The package of claim 9 further comprising a third encapsulant encapsulating the first package component and the second package component therein.

11. The package of claim 9, wherein the build-up package substrate further comprises:
a first plurality of redistribution lines on a first side of the interconnect die, wherein the first plurality of redistribution lines electrically connect the first package component and the second package component to the interconnect die.

12. The package of claim 11, wherein the build-up package substrate further comprises:
a second plurality of redistribution lines on a second side of the interconnect die, wherein the second plurality of redistribution lines electrically connect the first package component and the second package component to the organic package substrate.

13. The package of claim 8, wherein the first encapsulant of the build-up package substrate comprises a first edge, and the organic package substrate comprises a second edge, and the second edge is laterally recessed more toward a center vertical line of the organic package substrate than the build-up package substrate.

14. The package of claim 8 further comprising a passive device die between the build-up package substrate and the organic package substrate.

15. The package of claim 8, wherein the build-up package substrate further comprises a through-via in the first encapsulant.

16. The package of claim 15, wherein the build-up package substrate further comprises a redistribution line, wherein a portion of the redistribution line is in the first encapsulant, and physically contacts the through-via.

17. A package comprising:
an organic package substrate;
a build-up package substrate over and electrically coupled to the organic package substrate, wherein the build-up package substrate extends laterally beyond edges of the organic package substrate, and wherein the build-up package substrate comprises:
an interconnect die; and
a first encapsulant encapsulating the interconnect die therein;
a second encapsulant encapsulating the organic package substrate therein, wherein first edges of the first encapsulant are flush with second edges of the second encapsulant; and
device dies over and electrically coupled to the build-up package substrate, wherein the device dies are electrically interconnected through the interconnect die.

18. The package of claim 17, wherein the build-up package substrate comprises a first dielectric layer under the interconnect die, wherein the first dielectric layer comprises third edges flushed with the first edges of the first encapsulant.

19. The package of claim 17, wherein the build-up package substrate comprises a second dielectric layer over the interconnect die, wherein the second dielectric layer comprises fourth edges flushed with the first edges of the first encapsulant.

20. The package of claim 17, wherein the build-up package substrate further comprises a redistribution line, wherein a portion of the redistribution line is in the first encapsulant.
